(19) United States
(12) Patent Application Publication
(10) Pub. No.: US 2016/0240815 A1
(43) Pub. Date: Aug. 18, 2016

(54) OPTOELECTRONIC COMPONENT, OPTOELECTRONIC ASSEMBLY, METHOD FOR PRODUCING AN OPTOELECTRONIC COMPONENT AND METHOD FOR PRODUCING AN OPTOELECTRONIC ASSEMBLY

(71) Applicant: OSRAM OLED GMBH, Regensburg (DE)

(72) Inventors: Johannes Rosenberger, Regensburg (DE); Thomas Wehlus, Lappersdorf (DE)

(21) Appl. No.: 15/030,605

(22) PCT Filed: Oct. 22, 2014
(86) PCT No.: PCT/EP2014/072664

§ 371 Date: Apr. 20, 2016

(30) Foreign Application Priority Data
Oct. 24, 2013 (DE) 10 2013 111 732.5

(51) Int. Cl. H01L 51/52; H01L 51/44

(52) U.S. Cl. CPC H01L 51/5253; H01L 51/448

(57) ABSTRACT

An optoelectronic component may include an electrically conductive carrier structure having a first contact section and a carrier section, an organic functional layer structure which is formed above the carrier structure and which overlaps the carrier section and which does not overlap the first contact section, an electrically conductive covering structure, which is formed above the organic functional layer structure and which includes a covering section and a second contact section, wherein the covering section overlaps the organic functional layer structure and the carrier section, wherein the first contact section projects below the organic functional layer structure on a first side and on a third side of the optoelectronic component.

### RELATED APPLICATIONS

The present application is a national stage entry according to 35 U.S.C. §371 of PCT application No.: PCT/EP2014/072664 filed on Oct. 22, 2014, which claims priority from German application No.: 10 2013 111 732.5 filed on Oct. 24, 2013, and is incorporated herein by reference in its entirety.

### TECHNICAL FIELD

Various embodiments relate to an optoelectronic component, an optoelectronic assembly, a method for producing an optoelectronic component and a method for producing an optoelectronic assembly.

### BACKGROUND

Optoelectronic components on an organic basis, for example organic light emitting diodes (OLEDs), for example a white organic light emitting diode (WOLED), or an organic solar cell, are being used increasingly widely. By way of example, OLEDs are being used increasingly in general lighting, for example as a surface light source. An organic optoelectronic component may include an anode and a cathode with an organic functional layer system therebetween.

Conventional OLEDs are limited with regard to their size by the conductivities of their transparent electrodes. Even with highly developed electrode materials, such as silver nanowires (Ag nanowires), for example, lateral extents of only approximately 10 cm are possible. A busbar grid that is electrically coupled to the corresponding electrode and that can extend over the OLED can increase this structure size, but overwhelmingly dominates the appearance of the OLED in the case of larger areas, since higher and higher area occupancies by the metal of the busbar grids become necessary with increasing size. Alternatively or additionally, multiply stacked OLEDs can be used in order to reduce the effects of voltage variations over the active area of the OLED. Moreover, there is the possibility of supplying large areas with current by means of on-plate tiling, in which the cathode of an OLED pixel is directly interconnected with the anode of the next pixel.

### SUMMARY

In various embodiments, an optoelectronic component is provided which makes it possible to produce an optoelectronic assembly of virtually any desired size without greatly reducing the useable area and/or with a minimal loss of luminous area, and/or to produce optoelectronic assemblies having different shapes and sizes.

In various embodiments, an optoelectronic assembly is provided which can be of virtually any desired size without a useable area being greatly reduced and/or with a minimal loss of luminous area, and/or which is producible with different shapes and sizes.

In various embodiments, a method for producing an optoelectronic component is provided which makes it possible, by means of the component, to produce an optoelectronic assembly of virtually any desired size without greatly reducing the useable area and/or with a minimal loss of luminous area, and/or to produce optoelectronic assemblies having different shapes and sizes.

In various embodiments, a method for producing an optoelectronic assembly is provided which makes it possible to produce an optoelectronic assembly of virtually any desired size without greatly reducing the useable area and/or with a minimal loss of luminous area, and/or to produce the optoelectronic assembly with different shapes and sizes.

In various embodiments, an optoelectronic component is provided. The optoelectronic component has a carrier structure including a first contact section and a carrier section. An organic functional layer structure is formed above the carrier structure and overlaps the carrier section. The organic functional layer structure does not overlap the first contact section. An electrically conductive covering structure is formed above the organic functional layer structure and includes a covering section and a second contact section. The covering section overlaps the organic functional layer structure and the carrier section. The first contact section projects below the organic functional layer structure on a first side and on a third side of the optoelectronic component. The covering structure does not overlap the first contact section. The second contact section does not overlap the organic functional layer structure and the first contact section. The second contact section projects above the organic functional layer structure on a second side and on a fourth side of the optoelectronic component. The carrier structure does not overlap the second contact section. The second side adjoins the third side. The first contact section is formed in an L-shaped fashion in plan view. The second side adjoins the fourth side. The second contact section is formed in an L-shaped fashion in plan view.

The first contact section and the second contact section, which do not overlap, enable current to be routed separately toward and away from the organic functional layer structure. In the case of an optoelectronic assembly including two or more of the optoelectronic components, this enables back-contacting from the second contact section of a first optoelectronic assembly to the first contact section of a second optoelectronic assembly in a simple manner. As a result, it is possible, in a simple manner, to realize large optoelectronic assemblies, for example optoelectronic assemblies of any desired size, which have only a small loss of active luminous area, for example in the region of contact points at which the optoelectronic components are connected to one another.

Furthermore, the optoelectronic components are connected to form a large-area assembly only upon arrangement of the covering bodies and associated lamination and/or encapsulation or afterward. This makes it possible, for example, firstly to test the individual optoelectronic assemblies and to use them, or not use them, depending on the test result for the optoelectronic assembly. This can contribute to minimizing rejects. Furthermore, this makes it possible to produce optoelectronic assemblies having different sizes and shapes by means of a skillful arrangement of the optoelectronic components, for example of identical optoelectronic components.

The fact that the first contact section and the second contact section do not overlap means, for example, that a straight line which intersects the first contact section and is perpendicular to the first contact section does not intersect the second contact section, and/or that a straight line which intersects the second contact section and which is perpendicular to the second contact section does not intersect the first contact section. The fact that the first contact section and the second contact section do not overlap means, for example, that the carrier and the covering body are displaced relative to one another and only partly overlap; in particular only the carrier section and the covering section overlap.

In various embodiments, the carrier structure includes a carrier and a first electrode. The first electrode is formed in the carrier section between the carrier and the organic functional layer structure. Alternatively or additionally the covering structure includes a covering body and a second electrode. The second electrode is formed in the covering section between the organic functional layer structure and the covering body. Optionally, the first electrode can extend at least partly over the first contact section and/or the second electrode can extend at least partly over the second contact section.

The carrier can be formed completely from electrically conductive material. By way of example, the carrier can be formed integrally from an electrically conductive material or the carrier may include an electrically conductive main body and an electrically conductive carrier layer. As an alternative thereto, the carrier can be formed only partly from electrically conductive material. By way of example, the carrier may include an electrically insulating main body and an electrically conductive carrier layer. If appropriate, the electrically conductive carrier layer is electrically coupled to the first electrode and/or the organic functional layer structure and faces the first electrode and/or the organic functional layer structure.

The covering body can be formed completely from electrically conductive material. By way of example, the covering body can be formed integrally from an electrically conductive material or the covering body may include an electrically conductive main body and an electrically conductive covering layer. As an alternative thereto, the covering body can be formed only partly from electrically conductive material. By way of example, the covering body may include an electrically insulating main body and an electrically conductive covering layer. If appropriate, the electrically conductive covering layer is electrically coupled to the second electrode and/or the organic functional layer structure and faces the second electrode and/or the organic functional layer structure. In particular, transparent optoelectronic assemblies of any desired size can be realized by the use of Ito glass as covering body or Ag nanowires integrated into the covering body, for example as an outer layer of the covering body.

In various embodiments, the first electrode extends at least partly over the first contact section. Alternatively, or additionally, the second electrode extends at least partly over the second contact section. By way of example, the first electrode extends over the entire first contact section and/or the second electrode extends over the entire second contact section.

In various embodiments, the electrically conductive carrier structure includes the carrier having the electrically conductive carrier layer. The electrically conductive carrier layer faces the organic functional layer structure and extends at least partly over the carrier section and the first contact section. Alternatively or additionally the electrically conductive covering structure includes the covering body having the electrically conductive covering layer. The electrically conductive covering layer faces the organic functional layer structure and extends at least partly over the covering section and the second contact section.

In various embodiments, the first electrode and/or the carrier structure lie(s) in a first plane and the second electrode and/or the covering structure lie(s) in a second plane. The first plane is at a predefined distance of greater than zero from the second plane. The sole electrically conductive connection between the first and second planes within the optoelectronic component is the organic functional layer structure. In other words, within the optoelectronic component there is no return routing and/or back-contacting from the second electrode in the second plane to the first plane in which the first electrode is formed. The return routing or back-contacting is effected only upon connection of a further optoelectronic component specifically toward the first electrode of the further optoelectronic component in the first plane.

In various embodiments, the first contact section projects below the organic functional layer structure on a first side of the optoelectronic component. The second contact section projects above the organic functional layer structure on a second side of the optoelectronic component. By way of example, the first side faces away from the second side and/or the first side does not touch the second side and/or the first side is parallel to the second side.

In various embodiments, the first contact section projects below the organic functional layer structure on a third side of the optoelectronic component. The second contact section of the covering body projects above the organic functional layer structure on a fourth side of the optoelectronic component. By way of example, the third side faces away from the fourth side and/or the third side does not touch the fourth side and/or the third side is parallel to the fourth side. By way of example, the first side touches the third side and the second side touches the fourth side and/or the first and second sides are connected to one another via the third and fourth sides.

In various embodiments, the first side adjoins the third side and the first contact section is formed in an L-shaped fashion in plan view. Alternatively or additionally, the second side adjoins the fourth side and the second contact section is formed in an L-shaped fashion in plan view. The fact that the contact sections are formed in an L-shaped fashion in plan view means, for example, that the contact sections appear L-shaped from a direction that is perpendicular to the contact sections and/or the first plane and/or the second plane.

In various embodiments, the optoelectronic component includes an encapsulation that encapsulates at least the exposed side edges of the organic functional layer structure. The encapsulation may include for example an encapsulation material, for example an electrically insulating encapsulation material. The encapsulation contributes to protecting the organic functional layer structure against harmful external influences, such as moisture or oxygen, for example.

In various embodiments, the optoelectronic component includes a barrier layer that covers the second electrode and that is formed in an electrically conductive fashion. The barrier layer contributes to protecting the second electrode against harmful external influences, such as moisture or oxygen, for example. The barrier layer may include for example an encapsulation material, for example an electrically conductive encapsulation material.

In various embodiments, the covering body is fixed to the second electrode or the barrier layer by means of an electrically conductive adhesion medium layer. The electrically conductive adhesion medium layer makes it possible in a simple manner, to fix the covering body to the second electrode and electrically couple it to the second electrode or the barrier layer.

In various embodiments, an optoelectronic assembly is provided. The optoelectronic assembly includes a first optoelectronic component, a second optoelectronic component and at least one third optoelectronic component. The first, second and third optoelectronic components can be formed in each case in accordance with a configuration of the optoelectronic component explained above. The first, second and third optoelectronic component are arranged in such a way that the first optoelectronic component is coupled at its second side to the first side of the second optoelectronic component and the second contact section of the first optoelectronic component overlaps the first contact section of the second optoelectronic component. The covering structure of the first optoelectronic component is electrically coupled to the carrier structure of the second optoelectronic component. The first optoelectronic component is coupled at its fourth side to the third side of the third optoelectronic component. The second contact section of the first optoelectronic component overlaps the first contact section of the third optoelectronic component. The covering structure of the first optoelectronic component is mechanically and electrically coupled to the carrier structure of the third optoelectronic component.

In various embodiments, the first optoelectronic component is electrically and/or mechanically coupled to the second optoelectronic component and/or to the third optoelectronic component by means of a connection element. The connection element can be for example a connection medium, for example an adhesion medium, for example an adhesive, or a profile rail. The connection element, for example the connection medium and/or the profile rail, can be formed in an electrically conductive fashion, for example. The connection medium can be a silver adhesive, for example. The profile rail may include or be formed from aluminum, silver or copper, for example.

In various embodiments, a method for producing an optoelectronic component is provided, wherein an electrically conductive carrier structure including a first contact section and a carrier section is formed. An organic functional layer structure is formed above the carrier structure in such a way that it overlaps the carrier section and does not overlap the first contact section. An electrically conductive covering structure including a covering section and a second contact section is arranged above the organic functional layer structure in such a way that the covering section overlaps the organic functional layer structure and the carrier section. The first contact section projects below the organic functional layer structure on a first side and on a third side of the optoelectronic component and the covering structure does not overlap the first contact section. The second contact section projects above the organic functional layer structure on a second side and on a fourth side of the optoelectronic component and does not overlap the carrier structure, the organic functional layer structure and the first contact section. The first side adjoins the third side and the first contact section is formed in an L-shaped fashion in plan view. The second side adjoins the fourth side and the second contact section is formed in an L-shaped fashion in plan view.

In various embodiments, a method for producing an optoelectronic assembly is provided, for example the optoelectronic assembly explained above. The first, second and at least the third optoelectronic components are arranged in such a way that the first optoelectronic component is coupled at its second side to the first side of the second optoelectronic component and the second contact section of the first optoelectronic component overlaps the first contact section of the second optoelectronic component. The carrier structure of the first optoelectronic component is electrically coupled to the carrier structure of the second optoelectronic component. The first optoelectronic component is coupled at its fourth side to the third side of the third optoelectronic component and the second contact section of the first optoelectronic component overlaps the first contact section of the third optoelectronic component. The covering structure of the first optoelectronic component is electrically coupled to the carrier structure of the third optoelectronic component.

### BRIEF DESCRIPTION OF THE DRAWINGS

The invention is explained in greater detail below on the basis of an exemplary embodiment, wherein also as before no distinction will be drawn specifically among the claim categories and the features in the context of the independent claims are intended also to be disclosed in other combinations. In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a sectional illustration of a conventional optoelectronic component;

FIG. 2 shows a detailed sectional illustration of a layer structure of the conventional optoelectronic component in accordance with FIG. 1;

FIG. 3 shows a sectional illustration of one exemplary embodiment of an optoelectronic component;

FIG. 4 shows a sectional illustration of one exemplary embodiment of an optoelectronic component;

FIG. 5 shows a sectional illustration of one exemplary embodiment of an optoelectronic component;

FIG. 6 shows a sectional illustration of one exemplary embodiment of an optoelectronic component;

FIG. 7 shows a plan view of one exemplary embodiment of an optoelectronic component;

FIG. 8 shows a plan view of one exemplary embodiment of an optoelectronic component;

FIG. 9 shows a plan view of one exemplary embodiment of an optoelectronic component;

FIG. 10 shows a sectional illustration of the optoelectronic assembly in accordance with FIG. 9 or 11;

FIG. 11 shows a plan view of one exemplary embodiment of an optoelectronic assembly;

FIG. 12 shows a sectional illustration of one exemplary embodiment of an optoelectronic assembly;

FIG. 13 shows a plan view of one exemplary embodiment of an optoelectronic assembly;

FIG. 14 shows a section illustration of one exemplary embodiment of an optoelectronic assembly;

FIG. 15 shows a plan view of one exemplary embodiment of an optoelectronic assembly;

FIG. 16 shows a flow diagram of one exemplary embodiment of a method for producing an optoelectronic component;

FIG. 17 shows a flow diagram of one exemplary embodiment of a method for producing an optoelectronic assembly.

### DETAILED DESCRIPTION

In the following detailed description, reference is made to the accompanying drawings, which form part of this description and show for illustration purposes specific exemplary embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of exemplary embodiments can be positioned in a number of different orientations, the direction terminology serves for illustration and is not restrictive in any way whatsoever. It goes without saying that other exemplary embodiments can be used and structural or logical changes can be made, without departing from the scope of protection of the present invention. It goes without saying that the features of the various exemplary embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

An optoelectronic assembly may include one, two or more optoelectronic components. Optionally, an optoelectronic assembly may also include one, two or more electronic components. An electronic component may include for example an active and/or a passive component. An active electronic component may include for example a computing, control and/or regulating unit and/or a transistor. A passive electronic component may include for example a capacitor, a resistor, a diode or a coil.

An optoelectronic component can be an electromagnetic radiation emitting component or an electromagnetic radiation absorbing component. An electromagnetic radiation absorbing component can be a solar cell, for example. An electromagnetic radiation emitting component can be formed for example as an organic electromagnetic radiation emitting diode or as an organic electromagnetic radiation emitting transistor. The radiation can be light in the visible range, UV light or infrared light, for example. In this context, the electromagnetic radiation emitting component can be formed for example as an organic light emitting diode (OLED) or as an organic light emitting transistor. In various exemplary embodiments, the light emitting component can be part of an integrated circuit. Furthermore, a plurality of light emitting components can be provided, for example in a manner accommodated in a common housing.

The term “translucent” or “translucent layer” can be understood to mean that a layer is transmissive to light, for example to the light emitted by a light-emitting component, for example in one or a plurality of wavelength ranges, for example to light in a wavelength range of visible light (for example at least in one partial range of the wavelength range of 380 nm to 780 nm). By way of example, in various exemplary embodiments, the term “translucent layer” should be understood to mean that substantially the entire quantity of light coupled into a structure (for example a layer) is also coupled out from the structure (for example layer), wherein part of the light can be scattered in this case.

The term “transparent” or “transparent layer” can be understood mean that a layer is transmissive to light (at least in a partial range of the wavelength range of 380 nm to 780 nm), wherein light coupled into a structure (for example a layer) is also coupled out from the structure (for example layer) substantially without scattering or light conversion.

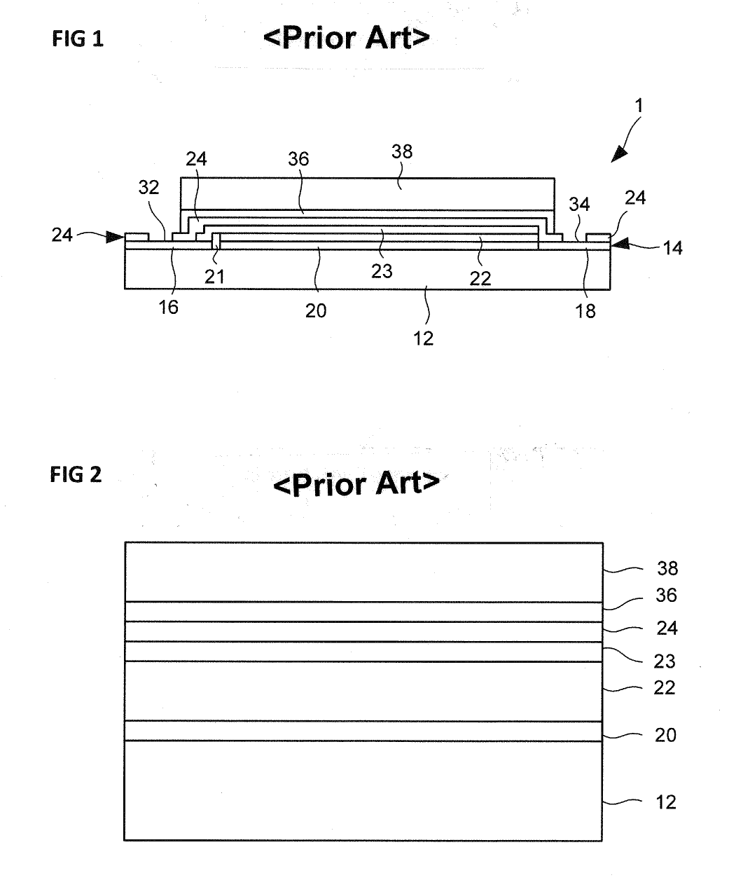

FIG. 1 shows a conventional optoelectronic component 1. The conventional optoelectronic component 1 includes a carrier 12, for example a substrate. A conventional optoelectronic layer structure is formed on the carrier 12.

The conventional optoelectronic layer structure includes a first electrode layer 14 including a conventional first contact section 16, a conventional second contact section 18 and a first electrode 20. The conventional second contact section 18 is electrically coupled to the first electrode 20 of the conventional optoelectronic layer structure. The first electrode 20 is electrically insulated from the conventional first contact section 16 by means of an electrical insulation barrier 21. An organic functional layer structure 22 of the conventional optoelectronic layer structure is formed above the first electrode 20. The optically functional layer structure 22 may include for example one, two or more partial layers, as explained in greater detail further below with reference to FIG. 2. A second electrode 23 of the optoelectronic layer structure is formed above the organic functional layer structure 22, said second electrode being electrically coupled to the conventional first contact section 16.

Assuming that the second electrode 23 is arranged in a first plane and the first electrode 20 is arranged in a second plane, in which the first contact section 16 and the second contact section 18 are also arranged, then during the operation of the conventional optoelectronic component 1, within the conventional optoelectronic component 1, an outgoing routing of the current takes place from the first electrode 20 via the organic functional layer structure 22 to the second electrode 23 and a return routing of the current takes place from the first plane to the second plane, in particular from the second electrode 23 to the first contact section 16.

The first electrode 20 serves for example as an anode or cathode of the optoelectronic layer structure. In a manner corresponding to the first electrode, the second electrode 23 serves as a cathode or anode of the optoelectronic layer structure.

An encapsulation layer 24 of the conventional optoelectronic layer structure is formed above the second electrode 23 and partly above the conventional first contact section 16 and partly above the conventional second contact section 18, said encapsulation layer encapsulating the conventional optoelectronic layer structure. In the encapsulation layer 24, a first cutout of the encapsulation layer 24 is formed above the conventional first contact section 16 and a second cutout of the encapsulation layer 24 is formed above the conventional second contact section 18. A first contact region 32 is exposed in the first cutout of the encapsulation layer 24 and a second contact region 34 is exposed in the second cutout of the encapsulation layer 24. The first contact region 32 serves for electrically contacting the conventional first contact section 16 and the second contact region 34 serves for electrically contacting the conventional second contact section 18.

An adhesion medium layer 36 is formed above the encapsulation layer 24. The adhesion medium layer 36 includes for example an adhesion medium, for example an adhesive, for example a lamination adhesive, a lacquer and/or a resin. A covering body 38 is formed above the adhesion medium layer 36. The adhesion medium layer 36 serves for fixing the covering body 38 to the encapsulation layer 24. The covering body 38 includes glass and/or metal, for example. For example, the covering body 38 can be formed substantially from glass and include a thin metal layer, for example a metal film, and/or a graphite layer, for example a graphite laminate, on the glass body. The covering body 38 serves for protecting the conventional optoelectronic component 1, for example against harmful external influences, for example against mechanical force actions from outside and/or against moisture or oxygen. Furthermore, the covering body 38 can serve for spreading and/or dissipating heat generated in the conventional optoelectronic component 1. By way of example, the glass of the covering body 38 can serve as protection against external actions and the metal layer of the covering body 38 can serve for spreading and/or dissipating the heat that arises during the operation of the conventional optoelectronic component 1.

The adhesion medium layer 36 can be applied to the encapsulation layer 24 in a structured fashion, for example. The fact that the adhesion medium layer 36 is applied to the encapsulation layer 24 in a structured fashion can mean, for example, that the adhesion medium layer 36 already has a predefined structure directly upon application. By way of example, the adhesion medium layer 36 can be applied in a structured fashion by means of a dispensing or printing method.

The conventional optoelectronic component 1 can be singulated from a component assemblage, for example, by the carrier 12 being scribed and then broken along its outer edges illustrated laterally in FIG. 1, and by the covering body 38 equally being scribed and then broken along its lateral outer edges illustrated in FIG. 1. The encapsulation layer 24 above the contact regions 32, 34 is exposed during this scribing and breaking. Afterward, the first contact region 32 and the second contact region 34 can be exposed in a further method step, for example by means of an ablation process, for example by means of laser ablation, mechanical scratching or an etching method.

FIG. 2 shows a detailed sectional illustration of a layer structure of a conventional optoelectronic component, for example of the conventional optoelectronic component 1 explained above, wherein the conventional contact sections 16, 18 are not illustrated in this detail view. The conventional optoelectronic component 1 can be formed as a top emitter and/or bottom emitter. If the conventional optoelectronic component 1 is formed as a top emitter and bottom emitter, the conventional optoelectronic component 0 can be referred to as an optically transparent component, for example a transparent organic light emitting diode.

The conventional optoelectronic component 1 includes the carrier 12 and an active region above the carrier 12. A first barrier layer (not illustrated), for example a first barrier thin-film layer, can be formed between the carrier 12 and the active region. The active region includes the first electrode 20, the organic functional layer structure 22 and the second electrode 23. The encapsulation layer 24 is formed above the active region. The encapsulation layer 24 can be formed as a second barrier layer, for example as a second barrier thin-film layer. The covering body 38 is arranged above the active region and, if appropriate, above the encapsulation layer 24. The covering body 38 can be arranged on the encapsulation layer 24 by means of an adhesion medium layer 36, for example.

The active region is an electrically and/or optically active region. The active region is, for example, that region of the conventional optoelectronic component 1 in which electric current for the operation of the conventional optoelectronic component 1 flows and/or in which electromagnetic radiation is generated or absorbed.

The organic functional layer structure 22 may include one, two or more functional layer structure units and one, two or more intermediate layers between the layer structure units.

The carrier 12 can be formed as translucent or transparent. The carrier 12 serves as a carrier element for electronic elements or layers, for example light emitting elements. The carrier 12 may include or be formed from, for example, glass, quartz, and/or a semiconductor material or any other suitable material. Furthermore, the carrier 12 may include or be formed from a plastics film or a laminate including one or including a plurality of plastics films. The plastic may include one or a plurality of polyolefins. Furthermore, the plastic may include polyvinyl chloride (PVC), polystyrene (PS), polyester and/or polycarbonate (PC), polyethylene terephthalate (PET), polyethersulfone (PES) and/or polyethylene naphthalate (PEN). The carrier 12 may include or be formed from a metal, for example copper, silver, gold, platinum, iron, for example a metal compound, for example steel. The carrier 12 can be formed as a metal film or metal-coated film. The carrier 12 can be a part of a mirror structure or form the latter. The carrier 12 can have a mechanically rigid region and/or a mechanically flexible region or be formed in this way.

The first electrode 20 can be formed as an anode or as a cathode. The first electrode 20 can be formed as translucent or transparent. The first electrode 20 includes an electrically conductive material, for example metal and/or a transparent conductive oxide (TCO) or a layer stack of a plurality of layers including metals or TCOs. The first electrode 20 may include for example a layer stack of a combination of a layer of a metal on a layer of a TCO, or vice versa. One example is a silver layer applied on an indium tin oxide (ITO) layer (Ag on ITO) or ITO—Ag—ITO multilayers. By way of example, Ag, Pt, Au, Mg, Al, Ba, In, Ca, Sm or Li, and compounds, combinations or alloys of these materials can be used as metal.

Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs.

The first electrode 20 may include, as an alternative or in addition to the materials mentioned: networks composed of metallic nanowires and nanoparticles, for example composed of Ag, networks composed of carbon nanotubes, graphene particles and graphene layers and/or networks composed of semiconducting nanowires. For example, the first electrode 20 may include or be formed from one of the following structures: a network composed of metallic nanowires, for example composed of Ag, which are combined with conductive polymers, a network composed of carbon nanotubes which are combined with conductive polymers, and/or graphene layers and composites. Furthermore, the first electrode 20 may include electrically conductive polymers or transition metal oxides.

The first electrode 20 can have for example a layer thickness in a range of 10 nm to 500 nm, for example of 25 nm to 250 nm, for example of 50 nm to 100 nm.

The first electrode 20 can have a first electrical terminal, to which a first electrical potential can be applied. The first electrical potential can be provided by an energy source (not illustrated), for example by a current source or a voltage source. Alternatively, the first electrical potential can be applied to the carrier 12 and the first electrode 20 can be supplied indirectly via the carrier 12. The first electrical potential can be for example the ground potential or some other predefined reference potential.

The organic functional layer structure 22 may include a hole injection layer, a hole transport layer, an emitter layer, an electron transport layer and/or an electron injection layer.

The hole injection layer can be formed on or above the first electrode 20. The hole injection layer may include or be formed from one or a plurality of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)benzidine); beta-NPB N,N′-bis(naphthalen-2-yl)-N,N′-bis(phenyl)-benzidine); TPD (N,N′-bis(3-methylphenyl)-N,N′-bis(phenyl)benzidine); Spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenyl-fluorene); DPFL-NPB (N,N′-bis(naphthalen-1-yl)-N,N′-bis(phenyl)-9,9-diphenylfluorene); Spiro-TAD (2,2′,7,7′-tetrakis(n,n-diphenylamino)-9,9′-spirobifluorene); 9, 9-bis[4-(N,N-bisbiphenyl-4-yl-amino)phenyl]-9H-fluorene; 9, 9-bis[4-(N,N-bis-naphthalen-2-yl-amino)phenyl]-9H-fluorene; 9,9-bis[4-(N,N′-bisnaphthalen-2-yl-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)-amino)-9,9-spirobifluorene; 2,2′-bis[N,N-bis(biphenyl-4-yl)amino]9,9-spirobifluorene; 2,2′-bis(N,N-diphenylamino) 9, 9-spirobifluorene; di-[4-(N,N-di-tolylamino)phenyl]cyclohexane; 2,2′,7,7′-tetra(N,N-di-tolyl)aminospirobifluorene; and/or N,N,N′,N′-tetra-naphthalen-2-yl-benzidine.

The hole injection layer can have a layer thickness in a range from approximately 10 nm to approximately 1000 nm, for example in a range from approximately 30 nm to approximately 300 nm, for example in a range from approximately 50 nm to approximately 200 nm.

The hole transport layer can be formed on or above the hole injection layer. The hole transport layer may include or be formed from one or a plurality of the following materials: NPB (N,N′-bis(naphthalen-1-yl)-N,N′-bis(phenyl)benzidine); beta-NPB N,N′-bis-(naphthalen-2-yl)-N,N′-bis(phenyl)benzidine); TPD (N,N′-bis(3-methylphenyl)-N,N′-bis(phenyl)benzidine); Spiro TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); Spiro-TAD (2,2′,7,7′-tetra-kis(n,n-diphenylamino)-9,9′-spirobifluorene); 9,9-bis-[4-(N,N-bisbiphenyl-4-yl-amino)phenyl]-9H-fluorene; 9,9-bis[4-(N,N-bisnaphthalen-2-yl-amino)phenyl]-9H-fluorene; 9,9-bis[4-(N,N′-bisnaphthalen-2-yl-N,N′-bisphenylamino)-phenyl]-9H-fluorene; N,N′-bis(phen-anthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]9,9-spirobifluorene; 2,2′-bis(N,N-diphenylamino) 9,9-spirobifluorene; di-[4-(N,N-ditolylamino)phenyl]cyclohexane; 2,2′,7,7′-tetra(N,N-ditolyl)aminospirobifluorene; and N,N,N′,N′-tetranaphthalen-2-yl-benzidine.

The hole transport layer can have a layer thickness in a range of approximately 5 nm to approximately 50 nm, for example in a range of approximately 10 nm to approximately 30 nm, for example approximately 20 nm.

The one or a plurality of emitter layers, for example including fluorescent and/or phosphorescent emitters, can be formed on or above the hole transport layer. The emitter layer may include organic polymers, organic polymeric molecules (“small molecules”) or a combination of these materials. The emitter layer may include or be formed from one or a plurality of the following materials: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl) iridium III), green phosphorescent Ir(ppy)3 (tris(2-phenylpyridine)iridium III), red phosphorescent Ru (dtb-bpy)3*2(PF6) (tris[4,4′-di-tert-butyl-(2,2′)-bipyridine]-ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited for example by means of thermal evaporation. Furthermore, polymer emitters can be used which can be deposited for example by means of a wet-chemical method, such as, for example, a spin coating method. The emitter materials can be embedded in a suitable manner in a matrix material, for example a technical ceramic or a polymer, for example an epoxy; or a silicone.

The first emitter layer can have a layer thickness in a range of approximately 5 nm to approximately 50 nm, for example in a range of approximately 10 nm to approximately 30 nm, for example approximately 20 nm. The emitter layer may include emitter materials that emit in one color or in different colors (for example blue and yellow or blue, green and red). Alternatively, the emitter layer may include a plurality of partial layers which emit light of different colors. By means of mixing the different colors, the emission of light having a white color impression can result. Alternatively or additionally, provision can be made for arranging a converter material in the beam path of the primary emission generated by said layers, which converter material at least partly absorbs the primary light and emits secondary light having a different wavelength, such that white light results from the combination of non-white primary light and non-white secondary light.

The electron transport layer can be formed, for example deposited, on or above the emitter layer. The electron transport layer may include or be formed from one or a plurality of the following materials: NET-18; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium; 4-(naphthalen-1-yl)-3,5-diphenyl-4H-1,2,4-triazole; 1,3-bis[2-(2,2′-bipyridin-6-yl)-1,3,4-oxadiazo-5-yl]-benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethyl-fluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f] [1,10]phenanthroline; phenyl-dipyrenylphosphine oxide; naphthalenetetra-carboxylic dianhydride or the imides thereof; perylenetetracarboxylic dianhydride or the imides thereof; and substances based on silols including a silacyclopentadiene unit.

The electron transport layer can have a layer thickness in a range of approximately 5 nm to approximately 50 nm, for example in a range of approximately 10 nm to approximately 30 nm, for example approximately 20 nm.

The electron injection layer can be formed on or above the electron transport layer. The electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolato lithium, 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2, 9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f] [1, 10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

The electron injection layer can have a layer thickness in a range of approximately 5 nm to approximately 200 nm, for example in a range of approximately 20 nm to approximately 50 nm, for example approximately 30 nm.

In the case of an organic functional layer structure 22 including two or more organic functional layer structure units, corresponding intermediate layers can be formed between the organic functional layer structure units. The organic functional layer structure units can be formed in each case individually by themselves in accordance with a configuration of the optically functional layer structure 22 explained above. The intermediate layer can be formed as an intermediate electrode. The intermediate electrode can be electrically connected to an external voltage source. The external voltage source can provide a third electrical potential, for example, at the intermediate electrode. However, the intermediate electrode can also have no external electrical terminal, for example by the intermediate electrode having a floating electrical potential.

The organic functional layer structure unit can have for example a layer thickness of a maximum of approximately 3 μm, for example a layer thickness of a maximum of approximately 1 μm, for example a layer thickness of a maximum of approximately 300 nm.

The conventional optoelectronic component 10 can optionally include further functional layers, for example arranged on or above the one or the plurality of emitter layers or on or above the electron transport layer. The further functional layers can be for example internal or external coupling-in/coupling-out structures that can further improve the functionality and thus the efficiency of the conventional optoelectronic component 10.

The second electrode 23 can be formed in accordance with one of the configurations of the first electrode 20, wherein the first electrode 20 and the second electrode 23 can be formed identically or differently. The second electrode 23 can be formed as an anode or as a cathode. The second electrode 23 can have a second electrical terminal, to which a second electrical potential can be applied. The second electrical potential can be provided by the same energy source as, or a different energy source than, the first electrical potential. The second electrical potential can be different than the first electrical potential. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

The encapsulation layer 24 can also be designated as thin-film encapsulation. The encapsulation layer 24 includes encapsulation material. The encapsulation layer 24 can be formed as a translucent or transparent layer. The encapsulation layer 24 forms a barrier against chemical impurities or atmospheric substances, in particular against water (moisture) and oxygen. In other words, the encapsulation layer 24 is formed in such a way that substances that can damage the optoelectronic component, for example water, oxygen or solvent, cannot penetrate through it or at most very small proportions of said substances can penetrate through it. The encapsulation layer 24 can be formed as an individual layer, a layer stack or a layer structure.

The encapsulation material, for example the encapsulation layer 24 and/or the barrier layer, may include or be formed from: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), nylon 66, and mixtures and alloys thereof.

The encapsulation layer 24 can have a layer thickness of approximately 0.1 nm (one atomic layer) to approximately 1000 nm, for example a layer thickness of approximately 10 nm to approximately 100 nm, for example approximately 40 nm.

The encapsulation layer 24 may include a high refractive index material, for example one or a plurality of material(s) having a high refractive index, for example having a refractive index of 1.5 to 3, for example of 1.7 to 2.5, for example of 1.8 to 2.

If appropriate, the first barrier layer can be formed on the carrier 12 and/or on the organic functional layer structure 22 in a manner corresponding to a configuration of the encapsulation layer 24.

The encapsulation layer 24 can be formed for example by means of a suitable deposition method, e.g. by means of an atomic layer deposition (ALD) method e.g. a plasma enhanced atomic layer deposition (PEALD) method or a plasmaless atomic layer deposition (PLALD) method, or by means of a chemical vapor deposition (CVD) method e.g. a plasma enhanced chemical vapor deposition (PECVD) method or a plasmaless chemical vapor deposition (PLCVD) method, or alternatively by means of other suitable deposition methods.

If appropriate, a coupling-in or coupling-out layer can be formed for example as an external film (not illustrated) on the carrier 12 or as an internal coupling-out layer (not illustrated) in the layer cross section of the optoelectronic component 10. The coupling-in/-out layer may include a matrix and scattering centers distributed therein, wherein the average refractive index of the coupling-in/-out layer is greater than the average refractive index of the layer from which the electromagnetic radiation is provided. Furthermore, in addition, one or a plurality of antireflection layers can be formed.

The adhesion medium layer 36 may include adhesive and/or lacquer, for example, by means of which the covering body 38 is arranged, for example adhesively bonded, on the encapsulation layer 24, for example. The adhesion medium layer 36 can be formed as transparent or translucent. The adhesion medium layer 36 may include for example particles which scatter electromagnetic radiation, for example light-scattering particles. As a result, the adhesion medium layer 36 can act as a scattering layer and lead to an improvement in the color angle distortion and the coupling-out efficiency.

The light-scattering particles provided can be dielectric scattering particles, for example composed of a metal oxide, for example, silicon oxide (SiO₂), zinc oxide (ZnO), zirconium oxide (ZrO₂), indium tin oxide (ITO) or indium zinc oxide (IZO), gallium oxide (Ga₂Oₓ), aluminum oxide, or titanium oxide. Other particles may also be suitable provided that they have a refractive index that is different than the effective refractive index of the matrix of the adhesion medium layer 36, for example air bubbles, acrylate, or hollow glass beads. Furthermore, by way of example, metallic nanoparticles, metals such as gold, silver, iron nanoparticles, or the like can be provided as light-scattering particles.

The adhesion medium layer 36 can have a layer thickness of greater than 1 μm, for example a layer thickness of a plurality of μm. In various exemplary embodiments, the adhesive can be a lamination adhesive.

The adhesion medium layer 36 can have a refractive index that is less than the refractive index of the covering body 38. The adhesion medium layer 36 may include for example a low refractive index adhesive such as, for example, an acrylate having a refractive index of approximately 1.3. However, the adhesion medium layer 36 can also include a high refractive index adhesive which for example includes high refractive index, non-scattering particles and has a layer-thickness-averaged refractive index that approximately corresponds to the average refractive index of the organic functional layer structure 22, for example in a range of approximately 1.6 to approximately 2.5, for example in a range of approximately 1.7 to approximately 2.0.

A so-called getter layer or getter structure, i.e. a laterally structured getter layer, can be arranged (not illustrated) on or above the active region. The getter layer can be formed as translucent, transparent or opaque. The getter layer may include or be formed from a material that absorbs and binds substances that are harmful to the active region. A getter layer may include or be formed from a zeolite derivative, for example. The getter layer can have a layer thickness of greater than 1 μm, for example a layer thickness of a plurality of μm. In various exemplary embodiments, the getter layer may include a lamination adhesive or be embedded in the adhesion medium layer 36.

The covering body 38 can be formed for example by a glass body, a metal film or a sealed plastics film covering body. The covering body 38 can be arranged on the encapsulation layer 24 or above the active region for example by means of frit bonding (glass frit bonding/glass soldering/seal glass bonding) by means of a conventional glass solder in the geometrical edge regions of the conventional optoelectronic component 10. The covering body 38 can have for example a refractive index (for example at a wavelength of 633 nm) of for example 1.3 to 3, for example of 1.4 to 2, for example of 1.5 to 1.8.

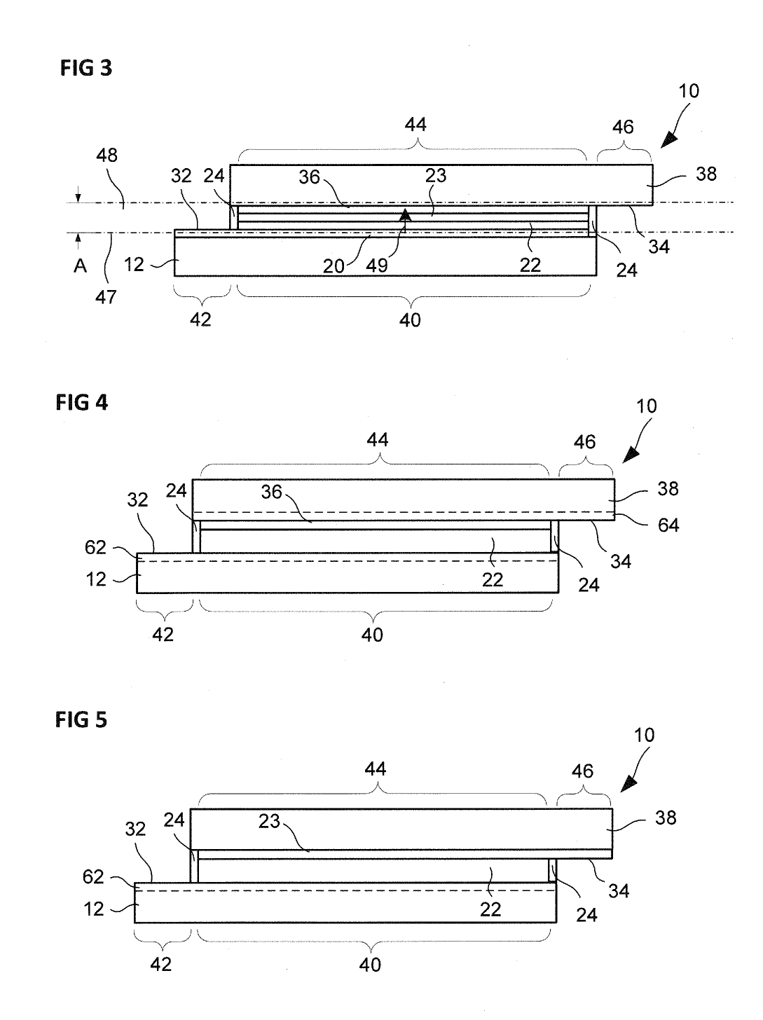

FIG. 3 shows a sectional illustration of one exemplary embodiment of an optoelectronic component 10. The optoelectronic component 10 and in particular the layers of the optoelectronic component 10 can for example largely correspond to the conventional optoelectronic component 1 and to the above-explained layers of the conventional optoelectronic component 1.

The optoelectronic component 10 includes a carrier structure including a carrier section 40 and a first contact section 42. The carrier structure includes for example the carrier 12 and the first electrode 20. The first electrode 20 extends over the carrier section 40 and over the first contact section 42. The organic functional layer structure 22 overlaps the carrier section 40 and does not overlap the contact section 42. In other words, the first electrode 20 is free of the organic functional layer structure 22 in the first contact section 42. The first electrode 20 and the carrier 12 project below the organic functional layer structure 22 at a first side of the optoelectronic component 10. The encapsulation layer 24 forms an encapsulation that encapsulates the organic functional layer structure 22 and the second electrode 23 at their lateral edges.

A covering structure is arranged above the organic functional layer structure 22. The covering structure includes a covering section 44 and a contact section 46. The covering structure includes the covering body 38 and optionally the second electrode 23 and/or the adhesion medium layer 36. The adhesion medium layer 36 and the covering body 38 are formed in an electrically conductive fashion. The covering structure is arranged in such a way that the covering section 44 is arranged above the organic functional layer structure 22 and the second electrode 23 and overlaps the latter and that the second contact section 46 does not overlap the organic functional layer structure 22 and/or the second electrode 23. Furthermore, the second contact section 46 does not overlap the carrier structure and/or the carrier section 40. Consequently, the second contact section 46 projects above the organic functional layer structure 22, such that the second contact region 34 is exposed.

The adhesion medium layer 36 is formed above the second electrode 23, if appropriate. As an alternative thereto, the adhesion medium layer 36 can also extend over the lateral edges of the second electrode 23 and of the organic functional layer structure 22 and/or replace the encapsulation layer 24. This can make it possible to be able to dispense with the encapsulation layer 24. Furthermore, a barrier layer can be formed between the second electrode 23 and the adhesion medium layer 36.

The covering structure is arranged in a first plane 47. The carrier structure, in particular the first electrode 20, is arranged in a second plane 48. The first plane 47 is at a predefined distance A, which is greater than zero, from the second plane 48. During the operation of the optoelectronic component 10, a current flow arises from the second plane 48 through the organic functional layer structure 22 along a current direction 49 to the first plane 47 and in particular from the carrier structure toward the covering structure, in particular from the first electrode 20 toward the second electrode 23 and further toward the covering body 38. In other words, there is no return routing of the current from the covering structure to the carrier structure within the optoelectronic component 10.

The contact sections 42, 46 are made relatively large compared with the covering sections 44 and carrier sections 40 in the figures which is intended to serve for affording a better understanding. In actual fact, however, the contact sections 42, 46 can also be made significantly smaller compared with the covering section 44 and the carrier section 40.

FIG. 4 shows a sectional illustration of one exemplary embodiment of an optoelectronic component 10 that can for example largely correspond to the optoelectronic component 10 explained above. In the case of the optoelectronic component 10, the carrier structure is formed in an electrically conductive fashion and the carrier structure includes no first electrode 20. Instead of the first electrode 20, the carrier 12 is formed in an electrically conductive fashion and/or the carrier 12 may include an electrically conductive carrier coating 62, such that the carrier 12 and/or the carrier coating 62 can perform the function of the first electrode 20.

Alternatively or additionally, the second electrode 23 can be dispensed with in the case of the covering structure in a manner corresponding to the carrier structure. By way of example, the covering body 38 can be formed in an electrically conductive fashion and/or the covering body 38 may include an electrically conductive covering coating 64, such that the covering body 38 and/or the covering coating 64 can perform the function of the second electrode 23. Furthermore, a barrier layer can be formed between the organic functional layer structure 22 and the adhesion medium layer 36.

FIG. 5 shows a sectional illustration of one exemplary embodiment of an optoelectronic component 10 that can for example largely correspond to the optoelectronic component 10 explained above. In the case of the optoelectronic component 10, the carrier structure is formed for example in accordance with the carrier structure shown in FIG. 4. The covering structure includes the second electrode 23. The second electrode 23 extends over the covering section 44 and the second contact section 46. Furthermore, a barrier layer can be formed between the organic functional layer structure 22 and the second electrode 23.

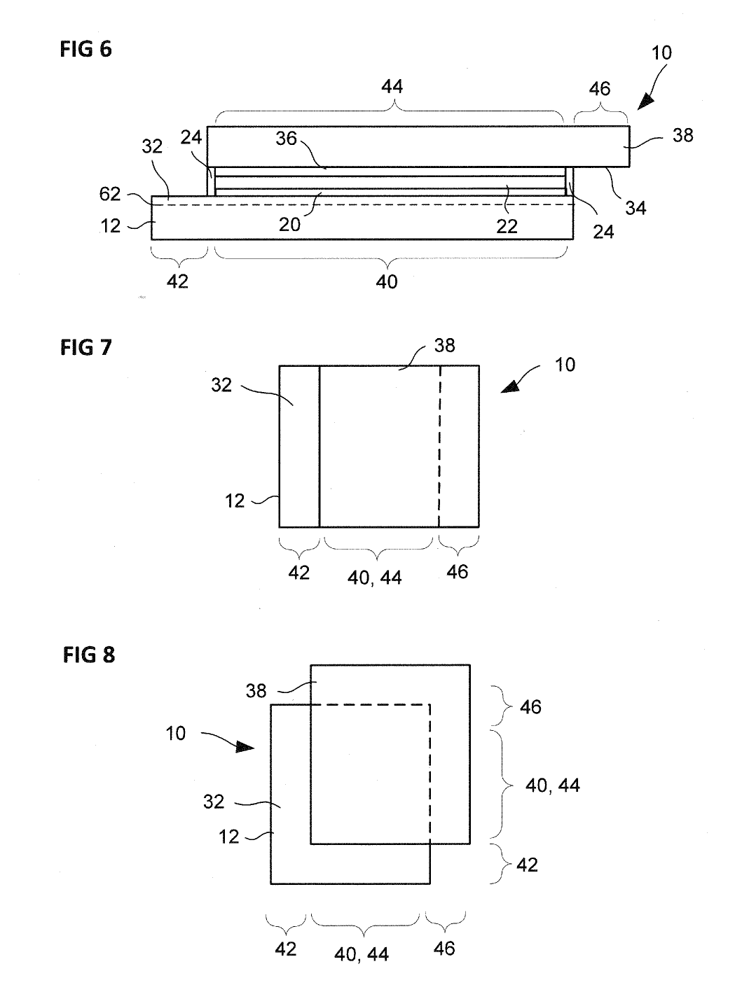

FIG. 6 shows a sectional illustration of one exemplary embodiment of an optoelectronic component 10 that can for example largely correspond to the optoelectronic component 10 explained above. In the case of the optoelectronic component 10, the covering structure is formed in accordance with the covering structure shown in FIG. 4. The carrier structure includes the carrier 12 and/or the electrically conductive carrier layer 62. The carrier 12 can be formed in an electrically conductive fashion, particularly if the carrier layer 62 is not formed. The carrier layer 62 extends over the carrier section 40 and the first contact section 42. The optoelectronic component 10 includes the first electrode 20. The first electrode 20 overlaps the carrier section 40. The first electrode 20 does not overlap the first contact section 42. The first electrode 20 does not overlap the first contact section 42. Furthermore, a barrier layer can be formed between the organic functional layer structure 22 and the adhesion medium layer 36.

FIG. 7 shows a plan view of one exemplary embodiment of an optoelectronic component 10, for example of one of the optoelectronic components 10 shown in FIGS. 3 to 6. The covering body 38 is displaced relative to the carrier 12 in such a way that on the first side of the optoelectronic component 10 the covering body 38 does not overlap the first contact section 42 and the first contact region 32 and the first contact region 32 is exposed. In a manner corresponding thereto, the second contact section 46 projects at the second side of the optoelectronic component 10, such that the second contact region 34 (concealed in FIG. 7) is exposed.

FIG. 8 shows a plan view of one exemplary embodiment of an optoelectronic component 10, for example of one of the optoelectronic components 10 shown in FIGS. 3 to 6. The covering body 38 is displaced relative to the carrier 12 in such a way that the covering body 38 does not overlap the first contact section 42 at the first and third sides of the optoelectronic component 10 and the first contact region 32 is exposed at the first and third sides of the optoelectronic component 10. The first contact section 42 and the first contact region 32 are formed in each case in an L-shaped fashion. In a manner corresponding thereto, the second contact section 46 projects at the second and fourth sides of the optoelectronic component 10 and the second contact region 34 (concealed in FIG. 8) is exposed at the second and fourth sides of the optoelectronic component 10. The second contact region 34 and the second contact section 46 are formed in an L-shaped fashion.

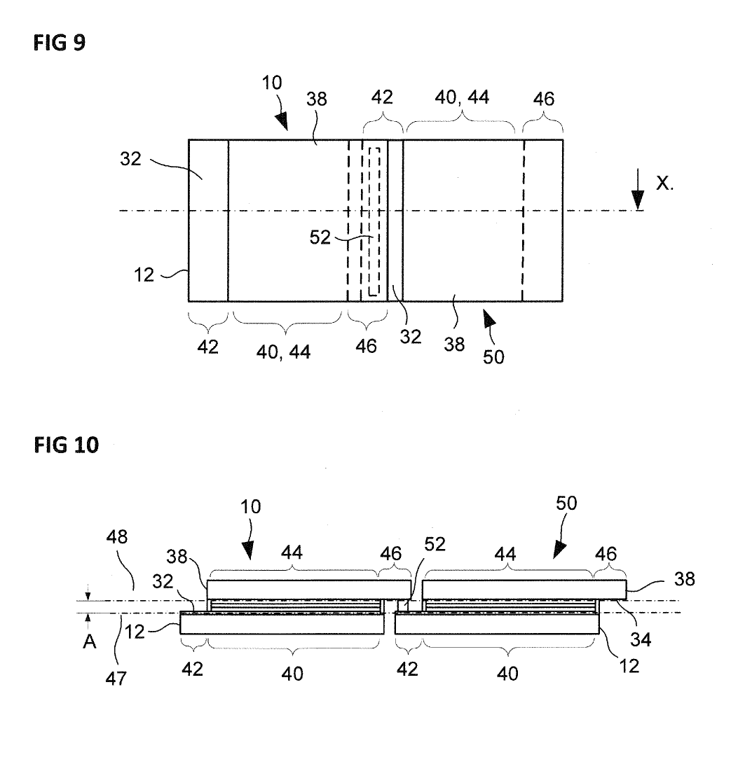

FIG. 9 shows a plan view of one exemplary embodiment of an optoelectronic assembly. The optoelectronic assembly includes at least two optoelectronic components that can in each case for example largely correspond to one of the optoelectronic components 10 explained above, for example the optoelectronic component 10 shown in FIG. 7. The optoelectronic assembly includes the optoelectronic component 10, for example the first optoelectronic component 10, and a second optoelectronic component 50.

The first optoelectronic component 10 is arranged by its second side at the first side of the second optoelectronic component 50. The first optoelectronic component 10 and the second optoelectronic component 50 are arranged with respect to one another in such a way that the second contact section 46 of the first optoelectronic component 10 overlaps the first contact section 42 of the second optoelectronic component 50.

A connection element is arranged in the overlap region and mechanically and electrically connects the two optoelectronic components 10, 50 to one another. The connection element includes a connection medium 52, for example. The connection medium 52 is formed in an electrically conductive fashion. By way of example, the connection medium 52 includes an electrically conductive adhesive, for example an adhesive including silver particles. The first optoelectronic component 10 and the second optoelectronic component 10 are mechanically and electrically coupled to one another by means of the connection medium 20. In particular, the covering structure of the first optoelectronic component 10 is mechanically and electrically connected to the carrier structure of the second optoelectronic component 50 via the connection medium 52.

During the operation of the optoelectronic assembly, a current flows for example from the carrier structure of the first optoelectronic component 10 via the organic functional layer structure 22 of the first optoelectronic component 10 to the covering structure of the first optoelectronic component 10. The current flows further from the covering structure of the first optoelectronic component 10 via the connection medium 52 to the carrier structure of the second optoelectronic component 50 and via the organic functional layer structure 22 of the second optoelectronic component 50 to the covering structure of the second optoelectronic component 50. The first optoelectronic component 10 and the second optoelectronic component 50 are electrically connected in series.

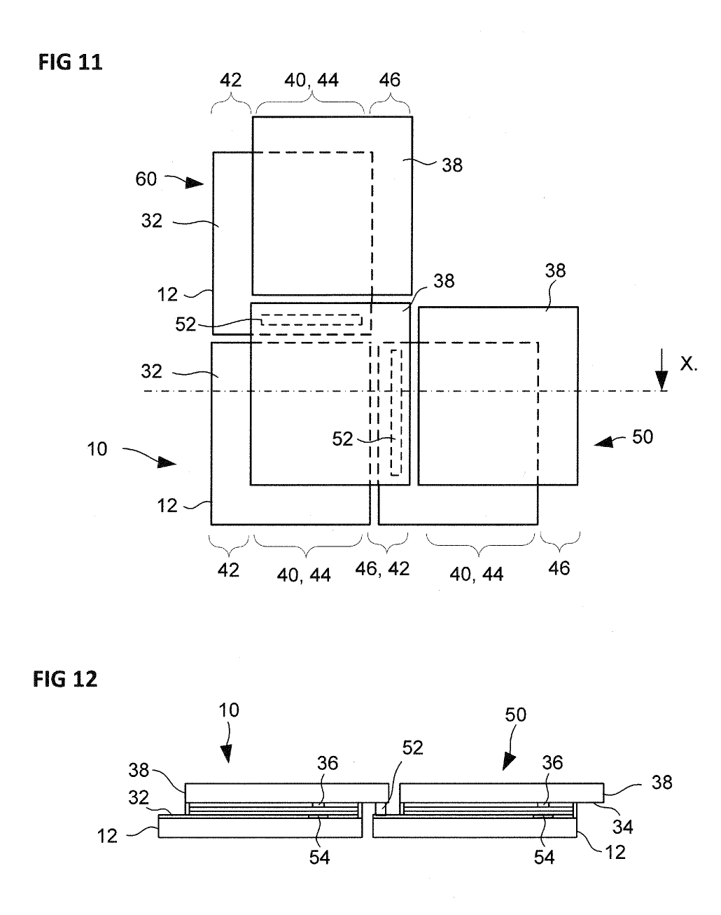

FIG. 10 shows a sectional illustration of one exemplary embodiment of an optoelectronic assembly, for example of the optoelectronic assembly shown in FIG. 9 or in FIG. 11. The optoelectronic assembly includes at least two optoelectronic components 10, 50 which are formed for example in accordance with the optoelectronic components 10 shown in FIGS. 3 to 6.

Optionally, three, four or more optoelectronic components 10, 50 can be coupled to one another, in particular connected in series with one another, in order to form the optoelectronic assembly. In other words, the optoelectronic assembly can also include more than two optoelectronic assemblies 10, 50.

FIG. 11 shows a plan view of one exemplary embodiment of an optoelectronic assembly. The optoelectronic assembly includes at least two optoelectronic components that can in each case for example largely correspond to one of the optoelectronic components 10 explained above, for example the optoelectronic component 10 shown in FIGS. 3 to 6 and 8. The optoelectronic assembly includes for example the first optoelectronic component 10, the second optoelectronic component 50 and a third optoelectronic component 60, which can be formed for example in accordance with a configuration of the first optoelectronic component 10.

The first optoelectronic component 10 is mechanically and electrically coupled at its second side to the first side of the second optoelectronic component 50, in particular by means of the connection medium 52. The first optoelectronic component 10 is mechanically and electrically coupled at its fourth side to a third side of the third optoelectronic component 60, in particular by means of the connection medium 52. Optionally, one, two or more further optoelectronic components 10 can also be mechanically and electrically coupled to the first, second and/or third optoelectronic component 10, 50, 60. A large-area optoelectronic assembly can be formed as a result. By way of example, the optoelectronic components 10, 50, 60 can be combined with one another in any desired shape and/or in any desired number, such that optoelectronic assemblies that are shaped in any desired way and are of any desired size can correspondingly be formed.

FIG. 12 shows a sectional illustration through one exemplary embodiment of an optoelectronic assembly. The optoelectronic assembly can for example largely correspond to one of the optoelectronic assemblies explained above. In the case of the optoelectronic components 10, 50 of the optoelectronic assembly, the corresponding adhesion medium layer 36 are applied only in a small, for example punctiform or circular, region. Below the adhesion medium layer 36 and below the corresponding small region, a respective cutout 54 is formed in the first electrode 20, specifically in such a way that the cutout 54 overlaps the corresponding adhesion medium layer 36 and the corresponding small region.

Since the second electrode 23 and the organic functional layer structure 22 can be made very thin, after the formation of the adhesion medium layer 36 only in the small region without the cutouts 54, in the event of a pressure on the adhesion medium layer 36, for exampled directly or indirectly via the covering body 38, the underlying region of the second electrode 23, of the organic functional layer structure 22 and/or of the first electrode 20 could be damaged. This could lead to a short circuit between the first electrode 20 and the second electrode 23 in the corresponding region. The cutout 54 has the effect that in the event of such damage giving rise to a conductive, low-resistance connection from the second electrode 23 through the organic functional layer structure 22, the conductive connection leads into the cutout 54 and does not result in a short circuit with the first electrode 20, since the latter is not present in the cutout 54.

Consequently, in the case where the adhesion medium layer 36 is applied in a locally restricted manner, formation of cutouts 54 in a manner corresponding thereto in the underlying first electrode 20 can contribute to short circuits being avoided and to the corresponding optoelectronic component 10, 50 and/or the optoelectronic assembly being able to be operated reliably.

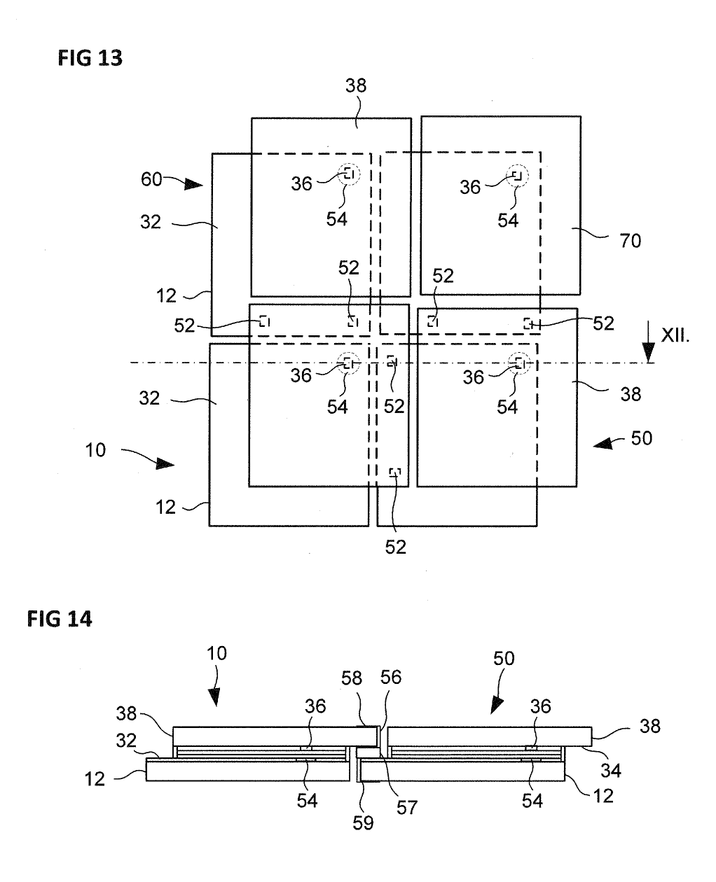

FIG. 13 shows a plan view of one exemplary embodiment of an optoelectronic assembly, for example the optoelectronic assembly in accordance with FIG. 12, wherein, in this exemplary embodiment, a fourth optoelectronic component 70 is also arranged in addition to the first, second and third optoelectronic components 10, 50, 60. The fourth optoelectronic component 70 can be formed for example in accordance with a configuration of the first optoelectronic component 10 explained above. Each of the optoelectronic components 10 includes the locally applied adhesion medium layer 36 and the cutouts 54 formed below the latter in the first electrode 20.

Alternatively or additionally, the connection media 52 are formed only in a locally delimited manner and/or in small regions shaped for example in a circular, punctiform or polygonal fashion.

FIG. 14 shows a sectional illustration through one exemplary embodiment of an optoelectronic assembly. The optoelectronic assembly includes the first and second optoelectronic component 10, 50, each of which can be formed for example in accordance with a configuration of the optoelectronic component 10 explained above. A profile rail 56 is arranged as connection element. The first and second optoelectronic components 10, 50 are mechanically and electrically coupled to one another by means of the profile rail 56. Optionally, one, two or more further optoelectronic components 10, 50, 60, 70 can also be coupled to one another by means of the profile rail 56 or one, two or more further profile rails 56.

The profile rail 56 may include or be formed from an electrically conductive material, for example. The profile rail 56 includes a central piece 57 arranged between the covering structure of the first optoelectronic component 10 and the carrier structure of the second optoelectronic component 50. Furthermore, the profile rail 56 includes an upper rail region 58, into which the covering structure of the first optoelectronic component 10 is inserted, and a lower rail region 59, into which the carrier structure of the second optoelectronic component 50 is inserted. Furthermore, the optoelectronic component 10, 50 includes the adhesion medium layer 36 applied in a locally delimited manner and the cutouts 54 corresponding thereto in the first electrode 20. As an alternative thereto, however, the adhesion medium layer 36 can be formed areally and the cutouts 54 can be dispensed with.

The connection elements shown above serve for the mechanical and electrical coupling of the optoelectronic components 10, 50 within an optoelectronic assembly. As an alternative thereto, for this purpose it is also possible to use first connection elements for mechanical coupling and second connection elements for electrical coupling, wherein the first connection elements differ from the second connection elements.

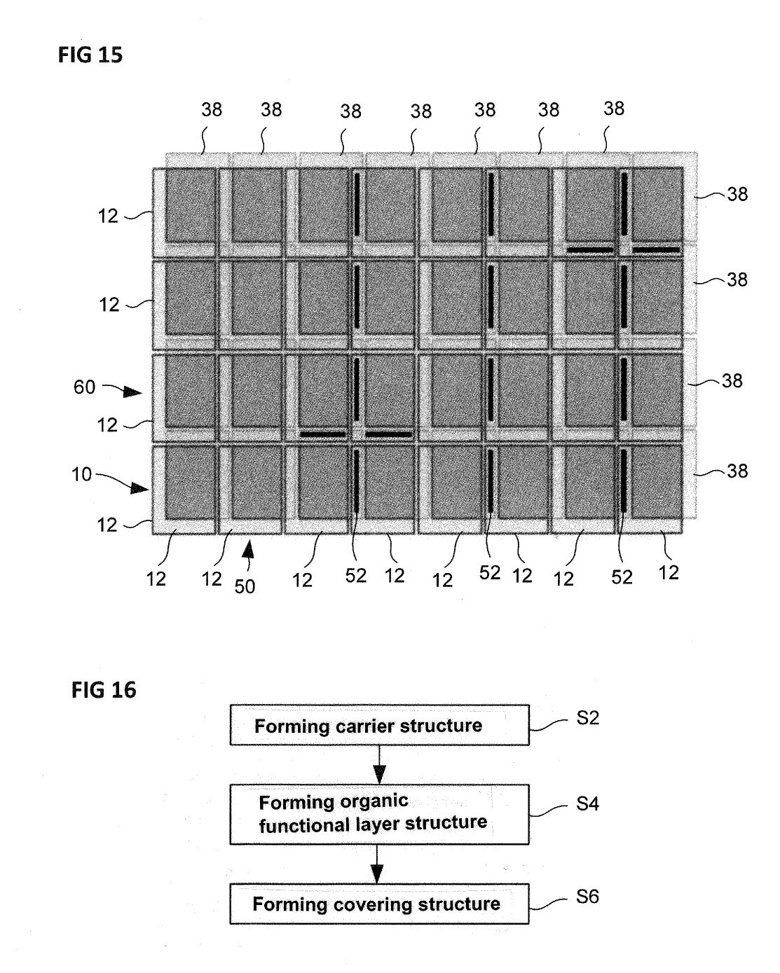

FIG. 15 shows a plan view of one exemplary embodiment of an optoelectronic assembly. The optoelectronic assembly includes the first, second and third optoelectronic components 10, 50, 60 and further optoelectronic components corresponding thereto. The optoelectronic components 10, 50, 60 can be coupled and/or connected to one another in diverse ways within the optoelectronic assembly, which is symbolized by sporadic depiction of connection media 52 in FIG. 12. As an alternative or in addition to the connection media 52, profile rails 56 can also be arranged.

FIG. 16 shows a flow diagram of one exemplary embodiment of a method for producing an optoelectronic component, for example the optoelectronic component 10.

A step S2 involves forming a carrier structure, for example the carrier structure explained above. For this purpose, by way of example, the carrier 12 is provided. Optionally, the carrier layer 62 can be formed on the carrier 12. Furthermore, the first electrode 20 can be formed above the carrier 12. Furthermore, if appropriate, a barrier layer can be formed on the carrier.

A step S4 involves forming an organic functional layer structure. By way of example, the organic functional layer structure 22 is formed above the carrier structure, specifically in such a way that it overlaps the carrier section 40 and does not overlap the first contact section 42.

A step S6 involves forming a covering structure, for example the covering structure explained above. By way of example, the second electrode 23 is formed above the organic functional layer structure 22. The covering body 38 is arranged above the organic functional layer structure 22 and, if appropriate, above the second electrode 23, specifically in such a way that the covering section 44 overlaps the organic functional layer structure 22 or the second electrode 23 and the second contact section 46 does not overlap the organic functional layer structure 22 or the second electrode 23. Before arranging the covering body 38, optionally it is also possible to form the covering layer 64 on the covering body 38.

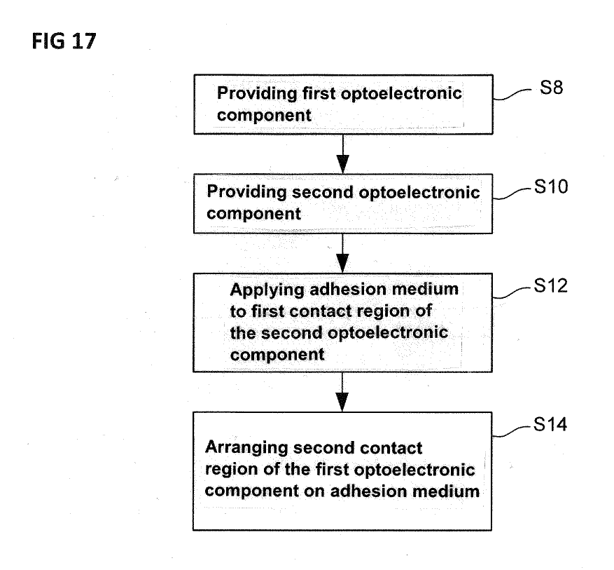

FIG. 17 shows a flow diagram of one exemplary embodiment of a method for producing an optoelectronic assembly, for example one of the optoelectronic assemblies explained above.

A step S8 involves providing a first optoelectronic component, for example the first optoelectronic component 10 explained above. By way of example, the first optoelectronic component 10 is produced, for example in accordance with the method explained with reference to FIG. 16.

A step S10 involves providing a second optoelectronic component, for example the second optoelectronic component 50 explained above. By way of example, the second optoelectronic component 50 is produced, for example in accordance with the method explained with reference to FIG. 16.

A step S12 involves applying a connection medium, for example the connection medium 52, to the first contact region 42 of the second optoelectronic component 50. As an alternative thereto, the profile rail 56 can be plugged onto the second optoelectronic component 50.

A step S14 involves arranging the first optoelectronic component 10 on the second optoelectronic component 50, for example by the second contact region 46 of the first optoelectronic component 10 being arranged on the connection medium 52 on the first contact region 42 of the second optoelectronic component 50. As an alternative thereto, the first optoelectronic component 10 is inserted by a second contact section 46 into the profile rail 46.

Optionally, even further optoelectronic components 10, 50, 60, 70 can be added to the optoelectronic assembly.

The invention is not restricted to the exemplary embodiments specified. By way of example, the optoelectronic components 10, 50, 60 shown may include more or fewer of the layers shown. By way of example, the optoelectronic components 10, 50, 60 may include one, two or more coupling-out structures, mirror layers, conversion layers and/or scattering layers. Furthermore, the exemplary embodiments shown can be combined with one another. By way of example, all the optoelectronic components 10, 50, 60 shown may include first contact sections 42 formed at the first and/or third side of the corresponding optoelectronic component 10, 50, 60 and the second contact sections 46 can be formed at the second and/or fourth sides of the corresponding optoelectronic component 10, 50, 60. Furthermore, the optoelectronic assembly can have any desired configuration of the optoelectronic components 10, 50, 60, 70 shown. Furthermore, larger, smaller or differently shaped optoelectronic assemblies can be formed with the aid of the optoelectronic components 10, 50, 60, 70. Furthermore, in addition to the one organic functional layer structure 22 shown, a plurality of organic functional layer structure units can be formed in one, two or more of the optoelectronic components 10, 50, 60, 70 shown.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component, comprising:
an electrically conductive carrier structure having a first contact section and a carrier section,
an organic functional layer structure which is formed above the carrier structure and which overlaps the carrier section and which does not overlap the first contact section,
an electrically conductive covering structure, which is formed above the organic functional layer structure and which comprises a covering section and a second contact section,
wherein the covering section overlaps the organic functional layer structure and the carrier section,
wherein the first contact section projects below the organic functional layer structure on a first side and on a third side of the optoelectronic component,
wherein the covering structure does not overlap the first contact section,
wherein the second contact section does not overlap the organic functional layer structure and the first contact section and projects above the organic functional layer structure on a second side and on a fourth side of the optoelectronic component,
wherein the carrier structure does not overlap the second contact section,
wherein the first side adjoins the third side and the first contact section is formed in an L-shaped fashion in plan view, and
wherein the second side adjoins the fourth side and the second contact section is formed in an L-shaped fashion in plan view.

2. The optoelectronic component as claimed in claim 1, wherein
the carrier structure comprises a carrier and a first electrode, which is formed in the carrier section between the carrier and the organic functional layer structure and/or
the covering structure comprises a covering body and a second electrode, which is formed in the covering section between the organic functional layer structure and the covering body.

3. The optoelectronic component as claimed in claim 2, wherein the first electrode extends at least partly over the first contact section and/or wherein the second electrode extends at least partly over the second contact section.

4. The optoelectronic component as claimed in claim 1, wherein
the electrically conductive carrier structure comprises a carrier having an electrically conductive carrier layer, wherein the electrically conductive carrier layer faces the organic functional layer structure and extends at least partly over the carrier section and the first contact section and/or
the electrically conductive covering structure comprises a covering body having an electrically conductive covering layer, wherein the electrically conductive covering layer faces the organic functional layer structure and extends at least partly over the covering section and the second contact section.

5. The optoelectronic component as claimed in claim 2, wherein the first electrode and/or the carrier structure lie(s) in a first plane and wherein the second electrode and/or the covering structure lie(s) in a second plane and wherein the first plane is at a predefined distance of greater than zero from the second plane and wherein the sole electrically conductive connection between the first and second planes within the optoelectronic component is the organic functional layer structure.

6. The optoelectronic component as claimed in claim 1, further comprising an encapsulation that encapsulates at least the exposed side edges of the organic functional layer structure.

7. The optoelectronic component as claimed in claim 2, further comprising a barrier layer that covers the second electrode and that is formed in an electrically conductive fashion.

8. The optoelectronic component as claimed in claim 2, wherein the covering body is fixed to the second electrode or the barrier layer by means of an adhesion medium layer, wherein the adhesion medium layer is formed in an electrically conductive fashion.

9. An optoelectronic assembly, comprising a first optoelectronic component, a second optoelectronic component and at least one third optoelectronic component,
the optoelectronic component, comprising:
an electrically conductive carrier structure having a first contact section and a carrier section,
an organic functional layer structure which is formed above the carrier structure and which overlaps the carrier section and which does not overlap the first contact section,
an electrically conductive covering structure, which is formed above the organic functional layer structure and which comprises a covering section and a second contact section,
wherein the covering section overlaps the organic functional layer structure and the carrier section,
wherein the first contact section projects below the organic functional layer structure on a first side and on a third side of the optoelectronic component,
wherein the covering structure does not overlap the first contact section,
wherein the second contact section does not overlap the organic functional layer structure and the first contact section and projects above the organic functional layer structure on a second side and on a fourth side of the optoelectronic component,
wherein the carrier structure does not overlap the second contact section,
wherein the first side adjoins the third side and the first contact section is formed in an L-shaped fashion in plan view, and
wherein the second side adjoins the fourth side and the second contact section is formed in an L-shaped fashion in plan view,
wherein the first optoelectronic component, the second optoelectronic component and the at least one third optoelectronic component are arranged in such a way,
that the first optoelectronic component is coupled at its second side to the first side of the second optoelectronic component and the second contact section of the first optoelectronic component overlaps the first contact section of the second optoelectronic component, wherein the covering structure of the first optoelectronic component is mechanically and electrically coupled to the carrier structure of the second optoelectronic component, and that the first optoelectronic component is coupled at its fourth side to the third side of the third optoelectronic component and the second contact section of the first optoelectronic component overlaps the first contact section of the third optoelectronic component, wherein the covering structure of the first optoelectronic component is mechanically and electrically coupled to the carrier structure of the third optoelectronic component.

10. The optoelectronic assembly as claimed in claim 9, wherein the first optoelectronic component is electrically and/or mechanically coupled to the second optoelectronic component and/or to the third optoelectronic component by means of a connection element.

11. A method for producing an optoelectronic component, the method comprising:
forming an electrically conductive carrier structure comprising a first contact section and a carrier section,
forming an organic functional layer structure above the carrier structure in such a way that it overlaps the carrier section and does not overlap the first contact section, and
arranging an electrically conductive carrier structure comprising a covering section and a second contact section above the organic functional layer structure in such a way
that the covering section overlaps the organic functional layer structure and the carrier section,
that the first contact section projects below the organic functional layer structure on a first side and on a third side of the optoelectronic component and the covering structure does not overlap the first contact section,
that the second contact section projects above the organic functional layer structure on a second side and on a fourth side of the optoelectronic component and does not overlap the carrier structure, the organic functional layer structure and the first contact section,
that the first side adjoins the third side and the first contact section is formed in an L-shaped fashion in plan view, and
that the second side adjoins the fourth side and the second contact section is formed in an L-shaped fashion in plan view.

12. (canceled)
